(19) United States
(12) Patent Application Publication
(10) Pub. No.: US 2025/0199580 A1
(43) Pub. Date: Jun. 19, 2025

(54) Smart Device Storage Module

(71) Applicant: Bayerische Motoren Werke Aktiengesellschaft, Muenchen (DE)

(72) Inventor: Etienne ILIFFE-MOON, Menlo Park, CA (US)

(21) Appl. No.: 18/389,732

(22) Filed: Dec. 19, 2023

(51) Int. Cl. G06F 1/16; B60H 1/00; B60R 7/04; B60R 16/03; G06F 1/20; H02J 7/00; H05K 7/20

(52) U.S. Cl. CPC G06F 1/1632; B60H 1/00507; B60R 7/04; B60R 16/03; G06F 1/203; H05K 7/20863; H02J 7/0044

(57) ABSTRACT

A storage device for a personal electronic device having a surface. The storage device includes a housing having a slot-aperture that connects a housing-external environment to a storage area enclosed by and internal to the housing. The storage area is configured to store the personal electronic device. The slot-aperture permits the personal electronic device to be inserted and removed manually from the storage area. The storage device also includes a protective buffer internal to the housing that contacts at least the surface so as to protect the personal electronic device from contact damage.

### BACKGROUND AND SUMMARY

The invention relates to improvements in the secure storage of personal electronic devices within motor vehicles, and more particularly to storage devices for such secure storage of personal electronic devices.

Personal electronic devices (e.g., laptops, smartphones, tablets, etc.) have become increasingly prevalent in society—and are indeed taken almost everywhere individuals may go, including during motor vehicle travel. Individuals often bring their personal electronic devices with them into the vehicle, because for example the devices may be used at the destination, or during the travel. The motor vehicle is, indeed, in many cases, seen as a mobile charging station for the personal electronic devices, which may be plugged into USB or other ports of the vehicle.

These personal devices are often thin, yet have a larger surface area that renders their temporary placement or storage in the vehicle less than satisfactory. For example, on long trips, devices may be stored in luggage that is itself stowed in the vehicle trunk. On shorter trips, devices may be simply placed on the vehicle seat, floor or backseat pouch. In such cases, the device may not be adequately secured from damage (e.g., due to sliding off the seat, etc.) or may be inadequately accessible (e.g., due to being stored in luggage, etc.).

Moreover, existing storage space within the motor vehicle is often limited and unsuitable for storage of such devices. For example, the glove box and center console are generally not sized to fit larger devices such as laptops and tablets. Even so, these traditional storage areas are often used as “junk storage” for keeping incidental and miscellaneous items, so are often already occupied with little remaining space. Thus, it is more common for such devices to be left in the open within the vehicle.

However, devices that are left in the open within the vehicle are subject to increased risk of theft. Such thefts are a substantial issue in urban environments, where there is often no safe place within the vehicle to store devices. For example, gloveboxes, center consoles and trunks can be easily broken into—with the vehicle interior itself likewise easily broken into.

As such, there is a need for storage devices that securely and conveniently store personal electronic devices within motor vehicles. Accordingly, storage devices are disclosed that overcome at least the disadvantages described herein.

More particularly, the storage device includes a housing having a slot-aperture that connects a housing-external environment to a storage area enclosed by and internal to the housing. The storage area is configured to store the personal electronic device. The slot-aperture permits the personal electronic device to be inserted and removed manually from the storage area. A protective buffer internal to the housing contacts at least the touch-screen surface so as to protect the personal electronic device from contact damage. The storage device may be secured to the vehicle in at least one of: an area adjacent to a seat of the vehicle such that the slot-opening is accessible by the user from the seat, and/or a trunk/frunk of the vehicle.

Other objects, advantages and novel features of the present invention will become apparent from the following detailed description of one or more preferred embodiments when considered in conjunction with the accompanying drawings.

### BRIEF DESCRIPTION OF THE DRAWINGS

FIG. 1 is a schematic illustration of an exemplary storage device according to one or more embodiments;

FIG. 2 is a schematic illustration of aspects of the exemplary storage device according to one or more embodiments; and

FIG. 3 is a schematic illustration of a vehicle having the exemplary storage device according to one or more embodiments.

### DETAILED DESCRIPTION OF THE DRAWINGS

The above described figures illustrate the present invention in at least one embodiment, which is further defined in detail in the following description. Those having ordinary skill in the art may be able to make alterations and modifications to what is described herein without departing from its spirit and scope. While the present invention is susceptible of embodiment in many different forms, there is shown in the drawings and will herein be described in detail at least one preferred embodiment of the invention with the understanding that the present disclosure is to be considered as an exemplification of the principles of the present invention, and is not intended to limit the broad aspects of the present invention to any embodiment illustrated.

In the following detailed description and corresponding figures, numerous specific details are set forth in order to provide a thorough understanding of the present invention. However, it should be appreciated that the invention may be practiced without such specific details. Additionally, well-known methods, procedures, components, and circuits have not been described in detail.

As used herein, the terms “a” or “an” shall mean one or more than one. The term “plurality” shall mean two or more than two. The term “another” is defined as a second or more. The terms “including” and/or “having” are open ended (e.g., comprising). The term “or” as used herein is to be interpreted as inclusive or meaning any one or any combination. Therefore, “A, B or C” means “any of the following: A; B; C; A and B; A and C; B and C; A, B and C”. An exception to this definition will occur only when a combination of elements, functions, steps or acts are in some way inherently mutually exclusive.

Reference throughout this document to “one embodiment,” “certain embodiments,” “an embodiment,” or similar term means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner on one or more embodiments without limitation.

The invention relates generally to systems and devices for in-vehicle storage of personal electronic devices.

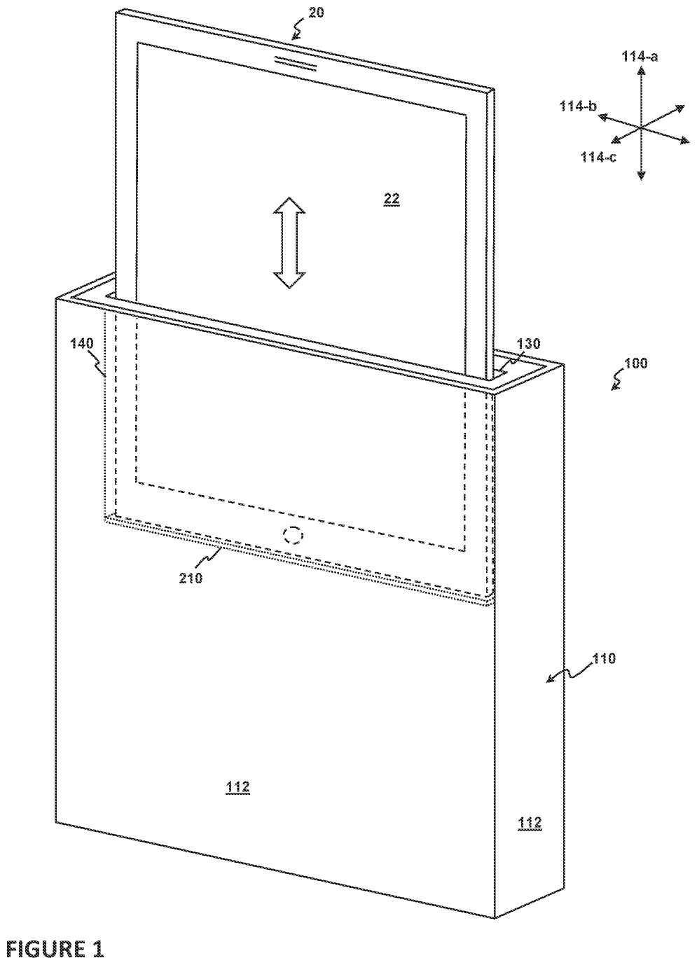

FIG. 1 schematically illustrates a storage device 100 for a personal electronic device 20 in accordance with at least one embodiment. Generally, the storage device 100 is configured to be located in a motor vehicle 10 such that the personal electronic device 20 may be securely and conveniently stored therein while remaining readily accessible to the user.

The personal electronic device 20 is generally a mobile computing device of a user, including but not limited to a tablet computer, a smartphone, a laptop computer, a personal digital assistant (PDA), a wearable, or the like. Accordingly, the personal electronic device 20 is preferably shaped so as to be a substantially rectangular tablet having opposing profile surfaces 22. The profile surfaces 22 may include, for example, operative surfaces, such as touch-screens, user-interfaces, etc., and inoperative surfaces, such as the top/bottom of a closed laptop. However, one of ordinary skill in the art will appreciate that other known shapes and configurations for the personal electronic device 20 are possible without departing from the scope of the invention.

The storage device 100 comprises a housing 110 configured to store the personal electronic device 20 therein. The housing 110 includes a plurality of walls 112 connected to each other along their respective edges so as to form the housing 110. Each of the plurality of walls 112 has an interior surface that faces interior to the housing 110, and an exterior surface that faces exterior to the housing 110. The housing 110 is preferably made of sturdy material (e.g., steel, hard polymer, composite, or the like) that is resistant to breaking. Moreover, the housing 110 is preferably secured to the vehicle 10 so as to substantially irremovable to a degree that deters theft from passersby.

The housing 110 further defines a storage area 120 that is enclosed by the plurality of walls 112 so as to be internal to the housing 110. The storage area 120 is configured (e.g., sized and shaped) such that the personal electronic device 20 is able to be stored therein.

At least one of the plurality of walls 112 comprises an aperture 130 that connects a housing-external environment 12 to a storage area. The housing-external environment 12 is external to the storage device 100. The aperture 130 is configured to permit the personal electronic device 20 to be manually inserted and/or removed from the storage area 120. In some embodiments, the aperture 130 is a slot-aperture configured to permit the passing of the personal electronic device 20 that has a substantially rectangular tablet shape. In addition to the aperture 130, the housing 110 may also comprise one or more debris-openings (not shown) configured to allow debris and other small objects to pass to the housing-external environment 12 or to a waste removal tray (not shown). The debris-openings are preferably not large enough for the personal electronic device 120 to pass through.

In at least one embodiment, the insertion and/or removal of the personal electronic device 20 via the slot substantially defines a primary axis 114-a of the housing 110. In other words, the direction along which the personal electronic device 20 is inserted to and/or removed from the housing 110 may be substantially along the primary axis 114-a. The housing 110 may further comprise a secondary axis 114-b and a tertiary axis 114-c, each normal to the primary axis 114-a and to each other. The primary axis 114-a and the secondary axis 114-b together define a plane that may be substantially parallel to the profile surface 22 when the personal electronic device 20 is stored within the storage area 120.

In at least one embodiment, the storage device 100 further comprises a protective buffer 140 configured to contact at least one surface of the personal electronic device 20 so as to protect the personal electronic device 20 from contact damage (e.g., due to vibration or other movement within the storage device 100). Accordingly, the protective buffer 140 preferably extends from the interior surface of at least one of the plurality of walls 112 to contact the personal electronic device 20. The protective buffer 140 is also preferably made of compliant material, such as silicone, rubber, TPE, TPR, polymer, felt or other similar protective material.

In some embodiments, the protective buffer 140 contacts at least two surfaces of the personal electronic device 20. For example, the protective buffer 140 may contact the personal electronic device 20 at the opposing profile surfaces 22 of the personal electronic device 20. Such contact may be substantially or fully enveloping to sporadically localized along the at least one surface. It at least one embodiment, the protective buffer 140 contacts at least the touch-screen surface of the personal electronic device 20.

In at least one embodiment, the storage device 100 further comprises an access control mechanism 150 configured to facilitate the insertion and/or removal of the personal electronic device 20. The access control mechanism 150 may be any mechanism by which insertion and/or removal of the personal electronic device 20 is fully or partially automated or otherwise assisted. For example, in at least one embodiment, the access control mechanism 150 is a drawer-like mechanism that opens and closes (like a drawer) to allow insertion/removal of the personal electronic device 20. In at least one other embodiment, the access control mechanism 150 is a disc-drive-like mechanism via which the user may insert/remove the personal electronic device 20. Other mechanisms may be utilized without departing from the scope of the invention.

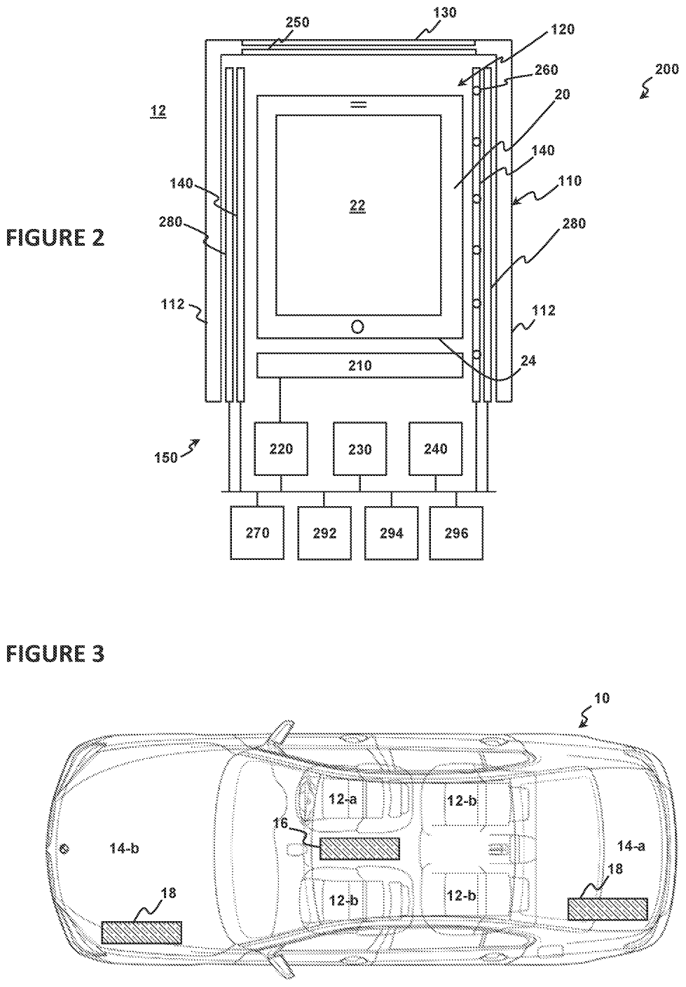

FIG. 2 schematically illustrates an exemplary architecture 200 showing aspects of the storage device 100 in accordance with at least one embodiment. As illustrated in FIG. 2, in some embodiments, the access control mechanism 150 comprises one or more of the components discussed in further detail herein. It will be understood by those of ordinary skill in the art that the aspects of such components may be combined with each other without departing from the scope of the invention.

In some embodiments, the storage device 100 comprises a moveable wall 210 (or other support) that is repositionable internal to the housing 110 along the primary axis 114-a. The moveable wall 210 may be configured to contact the personal electronic device 20 at an insertion surface 24 thereof (i.e., the surface of the personal electronic device 20 facing the insertion direction) so as to control the extent to which the personal electronic device 20 may be inserted into the storage area 120 via the aperture 130.

In some embodiments, the storage device 100 comprises a linear actuator 220 configured to actively reposition the moveable wall 210 internal to the housing 110. Accordingly, the linear actuator 220 may be any mechanical, electro-mechanical, or other linear actuator 220 whose operation autonomously or semi-autonomously repositions the moveable wall 210, or otherwise assists in the manual repositioning of the movable wall. The linear actuator 220 may, for example, comprise a linear spring, a motorized rack-and-pinion linear actuator, a motorized lead-screw linear actuator, or the like. It will be understood that the linear actuator 220 may be exchanged for a rotary actuator or any other type of actuator whose operation autonomously or semi-autonomously repositions the moveable wall 210, or otherwise assists in the manual repositioning of the movable wall, without departing from the scope of the invention.

In some embodiments, the storage device 100, particularly the access control mechanism 150, may be configured to provide a pulling force to the personal electronic device 20 as the personal electronic device 20 is inserted into the storage area 120 via the aperture 130. In other words, the personal electronic device 20 may be pulled, e.g., via the access control mechanism 150, into the storage area 120.

Additionally, or alternatively, the storage device 100, particularly the access control mechanism 150, may be configured to provide an ejecting force to the personal electronic device 20 as the personal electronic device 20 is removed from the storage area 120 via the aperture 130. In other words, the personal electronic device 20 may be pushed, e.g., via the access control mechanism 150, from the storage area 120. In particular, the personal electronic device 20 may be ejected from the storage area 120 so as to at least partially protrude from the aperture 130 into the housing-external environment 12. Accordingly, the personal electronic device 20 may thereafter be manually removed the remainder of the way from the storage device 100.

In some embodiments, the storage device 100 comprises an ejection-actuator 230 whose operation causes the access control mechanism 150 to mechanically or electro-mechanically provide the ejecting force. The ejection-actuator 230 may comprise one or more of: a touch sensor (e.g., capacitive sensing, etc.), a biometric sensor (e.g., voice, facial, fingerprint, etc. recognition), a proximity sensor (e.g., user, key fob, etc., proximity sensing), a vehicle in-use sensor (e.g., seat occupancy, key-in-ignition, ignition, etc.), configured to mechanically or electro-mechanically cause the personal electronic device 20 to be ejected. The ejection-actuator 230 may be located on the storage device 100 on the vehicle (e.g., console display, etc.), and/or on a secondary personal device (e.g., smartphone, PDA, wearable, etc.) of the user. Accordingly, the ejection-actuator 230 may comprise a software application (e.g., MyBMW app, etc.) running on the secondary personal device via which the user may control the ejection by, for example, touching a graphically displayed button on the secondary personal device. In at least one embodiment, the ejection-actuator 230 is a touch-activated button on the storage device 100.

In some embodiments, the storage device 100 may comprise an insertion-actuator (not shown) whose operation causes the access control mechanism to mechanically or electro-mechanically provide the pulling force and/or an insertion guiding force, for example, via the access control mechanism 150. The insertion-actuator 232 may comprise one or more of: a touch sensor (e.g., capacitive sensing, etc.), a biometric sensor (e.g., voice, facial, fingerprint, etc. recognition), a proximity sensor (e.g., user, key fob, etc., proximity sensing), a vehicle in-use sensor (e.g., seat occupancy, key-in-ignition, ignition, etc.), configured to mechanically or electro-mechanically cause the personal electronic device 20 to be inserted. The insertion-actuator 232 may be located on the storage device 100, on the vehicle (e.g., console display, etc.), and/or on a secondary personal device (e.g., smartphone, PDA, wearable, etc.) of the user. Accordingly, the insertion-actuator 232 may comprise a software application (e.g., MyBMW app, etc.) running on the secondary personal device via which the user may control the ejection by, for example, touching a graphically displayed button on the secondary personal device. In at least one embodiment, the insertion-actuator 232 is a touch-activated button on the storage device 100

In some embodiments, the storage device 100 comprises a locking mechanism 240 configured to prevent manual access to and/or removal of the personal electronic device 20 from the storage area 120. The locking mechanism 240 may be a mechanical and/or electrical lock. Moreover, the locking mechanism 240 may be controlled to lock/unlock via one or more of: a passcode, a physical key, a biometric sensor (e.g., voice, facial, fingerprint, etc. recognition), a proximity sensor (e.g., user, key fob, etc., proximity sensing), a vehicle in-use sensor (e.g., seat occupancy, key-in-ignition, ignition, etc.). In some embodiments, the locking mechanism 240 comprises a retractable, lockable cover that physically blocks the aperture 130. In some embodiments, the locking mechanism 240 may comprise the access control mechanism 150 operating in coordination with the ejection actuator to prevent ejection of the personal electronic device 20 until the storage device 100 is unlocked.

In some embodiments, the storage device 100 comprises one or more aperture coverings 250 configured to, at least in part, cover the aperture 130 so as to substantially prevent debris from entering the storage area 120 through the aperture 130. The aperture coverings 250 are preferably configured to permit the personal electronic device 20 to be inserted/removed manually from the storage area 120. Such aperture coverings 250 may be, for example, rubber flaps, brushes, or other small flexible elements.

In some embodiments, the storage device 100 comprises one or more rollers 260 (e.g., skid wheels) and/or sliders (e.g., track slides) (not shown) configured to function, at least in part, as the protective buffer 140 of the storage device 100. Accordingly, the rollers 260 and/or sliders may be made of silicone or other similar material. In such embodiments, the rollers 260 and/or sliders may also be configured to function, at least in part, as the linear actuator 220. In other words, the rollers 260 and/or sliders may be configured to contact at least one surface of the personal electronic device 20 so as to protect the personal electronic device 20 from contact damage, as well as to actively reposition the moveable wall 210 internal to the housing 110. Moreover, the rollers 260 and/or sliders may be configured to function, at least in part, as the locking mechanism 240, such that (a) in an unlocked state, the rollers 260 and/or sliders permit the insertion and/or removal of the personal electronic device 20, and (b) in a locked state, the rollers 260 and/or sliders frictionally prevent access to and removal of the personal electronic device 20 while stored within the storage area 120.

In some embodiments, the storage device 100 comprises a cooling mechanism 270 configured to cool the personal electronic device 20 while it is stored within the storage area 120. The cooling mechanism 270 may include one or more fans and/or ventilation ducts operative to pass air over the personal electronic device 20. In some embodiments, the cooling mechanism 270 is an extension of an HVAC system of the vehicle 10 and is operatively connected thereto. In at least one embodiment, the cooling mechanism 270 is actively controlled to cool the personal electronic device 20. For example, the cooling mechanism 270 may operate only while personal electronic device 20 is stored within the storage area 120—and may be deactivated or otherwise cut off from the HVAC system when the personal electronic device 20 is not stored within the storage area 120. In some embodiments, the cooling mechanism 270 may comprise an active cooling component such as, for example, a Peltier chip with a heatsink, alone or in combination with airflow.

In some embodiments, the storage device 100 comprises a sizing mechanism 280 configured to adjust the dimensions of the storage area 120 so as to accommodate personal electronic devices 20 of different sizes and/or orientations. The sizing mechanism 280 may comprise one or more brackets or other barriers internal to the housing 110 and configured to accept the personal electronic device 20. The brackets may be repositionable to accept different sized personal electronic devices 20, such that the position of the brackets define the storage area 120 dimensions. In at least one embodiment, one or more of the brackets may adjustably extend from respective inner surfaces of the plurality of walls 112 so as to functionally increase the width of the respective wall. In some embodiments, the sizing mechanism 280, e.g., the brackets, may include or otherwise comprise the protective barrier.

As further illustrated schematically in FIG. 2, in some embodiments, the storage device 100 may also comprise a charging interface 292 configured to operatively couple the personal electronic device 20 to a power source (e.g., a power grid of the motor vehicle 10) for charging or otherwise powering the personal electronic device 20. The charging interface 292 may comprise a charging input port configured to operatively couple to the power source. The charging input port is preferably a wired connection to the power source. The charging interface 292 may further comprise a charging output configured to operatively couple to the personal electronic device 20 so as to provide the charging. The charging interface 292 may comprise a wired connection, such as via lighting connect, USB-C connector, or the like, or a wireless connection, such as via Qi or other wireless charging connection.

In some embodiments, the storage device may comprise a retention mechanism (not shown) configured to provide a retaining force to the personal electronic device 20 so as to substantially retain the personal electronic device 20 within the storage area 120. Accordingly, the retention mechanism may function, at least in part, similar to the locking mechanism 240, except that the retention mechanism need not necessarily prevent manual removal but rather need only substantially keep the personal electronic device 20 from falling out of the storage device 100 while the vehicle is in motion. In some embodiments, the retention mechanism may comprise one or more magnets that retain the personal electronic device 20 within the storage area 120. In some embodiments, the retention device may comprise the charging interface 292. In particular, where the charging interface 292 is a wireless connection utilizing magnetic wireless charging, the charging interface 292 may also provide the retaining force of the retention mechanism. Moreover, the retention force may also maintain the personal electronic device 20 in an orientation sufficient for operative charging and/or data coupling, as described herein. In some embodiments, the retention mechanism may comprise the protective buffer 140 and/or the brackets of the sizing mechanism 280.

In some embodiments, the storage device 100 may also comprise a data interface 294 configured to operatively couple the personal electronic device 20 to one or more vehicle systems for exchanging data with the one or more vehicle systems. For example, the personal electronic device 20 may couple to an infotainment system of the vehicle 10 such that the personal electronic device 20 may be used in connection with the infotainment system (e.g., to play music, play music, make calls, etc.). The data interface 294 may comprise a wired and/or wireless data input port configured to operatively couple to the vehicle system. The data interface 294 may also comprise a wired and/or wireless data output port configured to operatively couple to the personal electronic device 20.

In some embodiments, the storage device 100 may also comprise a controller 296 configured to control one or more of the aforementioned components to operate as described herein. When such operations are implemented in software, code segments perform (or otherwise case the performance) of the certain tasks and/or functions described herein. The code segments can be stored in a computer readable medium. The term “computer readable medium,” as used herein, refers to any non-transitory media that participates in providing instructions to the processor for execution. Such a non-transitory medium may take many forms, including but not limited to volatile and non-volatile media. Non-volatile media includes, for example, optical or magnetic disks. Volatile media includes dynamic memory for example and does not include transitory signals, carrier waves, or the like. Examples of the computer readable mediums include an electronic circuit, a semiconductor memory device, a read-only memory (ROM), a flash memory or other non-volatile memory, a floppy diskette, a CD-ROM, an optical disk, a hard disk, etc.

FIG. 3 schematically illustrates the exemplary vehicle 10 with the storage device 100 described herein, in accordance with at least one embodiment. As described herein, the storage device 100 may be located conveniently within the vehicle 10 so as to be readily accessible by the user. The storage device 100 may be visible or may be concealed (e.g., by a faux panel or other component that blends in with the vehicle 10 interior).

In some embodiments, the storage device 100 may be located in a region 16 adjacent to a driver seat 12-a and/or passenger seat 12-b of the vehicle 10. For example, the storage device 100 may be located in one or more of: a center console region, a glovebox region, a side door region, a ceiling region, an under-seat region, an under-dashboard region, and the like. FIG. 3 shows the region 16 as the center console region as an illustrative example. One of ordinary skill in the art will appreciate that some of these regions may overlap.

In some embodiments, the storage device 100 may be located in a region 18 of a trunk and/or a frunk 14 of the vehicle 10, so as to be readily accessible by the user upon opening the trunk 14-a and/or frunk 14-b of the vehicle 10. FIG. 3 shows exemplary regions 18 as illustrative examples. Additionally, more than one storage device 100 may be located in the vehicle 10, with multiple storage devices 100 located in the same region or in different regions.

In some embodiments, the storage device 100 may be oriented within the region so as to permit the personal electronic device 20 to be manually inserted and/or removed from the storage area 120 with relative ease by the user. In other words, the orientation of the primary axis 114-a is preferably such that insertion/removal of the personal electronic device 20 is generally unobstructed by the vehicle 10. Such orientation may be substantially vertical, as for example with the storage device 100 located in a center console or side door regions, or substantially horizontal, as for example with the storage device 100 located in the ceiling or under seat regions. Such orientation may also be substantially angled so as to most efficiently orient the storage device 100 to be easily accessible by the user.

The embodiments described in detail above are considered novel over the prior art and are considered critical to the operation of at least one aspect of the described systems, methods and/or apparatuses, and to the achievement of the above described objectives. The words used in this specification to describe the instant embodiments are to be understood not only in the sense of their commonly defined meanings, but to include by special definition in this specification: structure, material or acts beyond the scope of the commonly defined meanings. Thus, if an element can be understood in the context of this specification as including more than one meaning, then its use must be understood as being generic to all possible meanings supported by the specification and by the word or words describing the element.

The definitions of the words or drawing elements described herein are meant to include not only the combination of elements which are literally set forth, but all equivalent structure, material or acts for performing substantially the same function in substantially the same way to obtain substantially the same result. In this sense, it is therefore contemplated that an equivalent substitution of two or more elements may be made for any one of the elements described and its various embodiments or that a single element may be substituted for two or more elements.

Changes from the subject matter as viewed by a person with ordinary skill in the art, now known or later devised, are expressly contemplated as being equivalents within the scope intended and its various embodiments. Therefore, obvious substitutions now or later known to one with ordinary skill in the art are defined to be within the scope of the defined elements. This disclosure is thus meant to be understood to include what is specifically illustrated and described above, what is conceptually equivalent, what can be obviously substituted, and also what incorporates the essential ideas.

Further, aspects of one or more embodiments are described herein with reference to operations that are performed by a computer system or a like electronic system. Such operations are sometimes referred to as being computer-executed. It will be appreciated that operations that are symbolically represented include the manipulation by a processor, such as a central processing unit, of electrical signals representing data bits and the maintenance of data bits at memory locations, such as in system memory, as well as other processing of signals. The memory locations where data bits are maintained are physical locations that have particular electrical, magnetic, optical, or organic properties corresponding to the data bits.

Furthermore, the operations described herein may be implemented via hardware, software, firmware or any combination thereof, unless expressly indicated otherwise. If implemented in software, the operations may be stored in a memory as one or more instructions on a computer readable medium, including any available media accessible by a computer that can be used to store desired program code in the form of instructions, data structures or the like. Thus, certain aspects may comprise a computer program product for performing the operations presented herein, such computer program product comprising a computer readable medium having instructions stored thereon, the instructions being executable by one or more processors to perform the operations described herein. It will be appreciated that software or instructions may also be transmitted over a transmission medium as is known in the art.

Further, various modules and/or other appropriate means for performing the operations described herein may be utilized in implementing the operations described herein. The term “module,” as used herein, includes hardware, firmware, software in execution on a machine, and/or combinations of each to perform a function(s) or an action(s), and/or to cause a function or action from another logic, method, and/or system. This may include software-controlled microprocessor(s), discrete logic (e.g., ASIC), analog circuit(s), digital circuit(s), programmed logic device(s), memory device(s) containing instructions, and so on. This may include one or more gates, combinations of gates, or other circuit components.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1. A storage device for a personal electronic device having a surface, the storage device comprising:
a housing having a slot-aperture that connects a housing-external environment to a storage area enclosed by and internal to the housing, wherein the storage area is configured to store the personal electronic device, and wherein the slot-aperture permits the personal electronic device to be inserted and removed manually from the storage area; and
a protective buffer internal to the housing that contacts at least the surface so as to protect the personal electronic device from contact damage.

2. The storage device of claim 1, wherein an insertion/removal axis, via which the slot-aperture permits insertion/removal of the personal electronic device, is parallel to the surface of the personal electronic device.

3. The storage device of claim 1, further comprising an access control mechanism configured to facilitate the insertion and/or removal of the personal electronic device.

4. The storage device of claim 3, wherein the access control mechanism is configured to pull the personal electronic device completely into the storage area.

5. The storage device of claim 3, wherein the access control mechanism is configured to eject the personal electronic device from the storage area so as to protrude from the slot-aperture to the housing-external environment.

6. The storage device of claim 5, wherein the access control mechanism includes an actuator via which the access control mechanism is actuatable by the user to eject the personal electronic device from the storage area.

7. The storage device of claim 3, wherein the access control mechanism includes a locking mechanism configured to prevent manual access to and removal of the personal electronic device while stored within the storage area.

8. The storage device of claim 6, wherein the locking mechanism includes an actuator via which the access control mechanism is actuatable by the user to permit manual access to and removal of the personal electronic device.

9. The storage device of claim 3,
wherein the protective buffer includes one or more rollers,
wherein the access control module comprises at least one of the rollers, and
wherein the rollers of the access control module are configured to: (a) in an unlocked state, permit the insertion and/or removal of the personal electronic device, and (b) in a locked state, prevent access to and removal of the personal electronic device while stored within the storage area.

10. The storage device of claim 1, wherein the access control mechanism is controllable via an interactive graphical-user-interface displayed by a vehicle display and/or a device display.

11. The storage device of claim 1, further comprising:
a power link configured to operatively connect the personal electronic device to an auxiliary power grid of a motor vehicle such that the personal electronic device is chargeable via the auxiliary power grid while stored within the storage area.

12. The storage device of claim 1, further comprising:
a data link configured to operatively connect the personal electronic device to an infotainment system of a motor vehicle such that the personal electronic device is useable in connection with the infotainment system.

13. The storage device of claim 1, further comprising:
a slot-covering that covers the slot-aperture while permitting the personal electronic device to be inserted and removed manually from the storage area.

14. The storage device of claim 1, further comprising:
a cooling mechanism configured to cool the personal electronic device while stored within the storage area.

15. The storage device of claim 1, further comprising:
a sizing mechanism configured to adjust the dimensions of the storage area so as to accommodate the personal electronic device.

16. A vehicle, comprising:
the storage device of claim 1,
wherein the storage device is secured to the vehicle in at least one of:
an area adjacent to a seat of the vehicle such that the slot-opening is accessible by the user from the seat,
a trunk of the vehicle, and
a frunk of the vehicle.

17. The vehicle of claim 16, wherein the area adjacent to the seat of the vehicle is: a center console area, a glovebox area, a side door area, a ceiling area, an under-seat area, or an under-dashboard area.
